(19) United States
(12) Patent Application Publication
(10) Pub. No.: US 2004/0077172 A1
(43) Pub. Date: Apr. 22, 2004

(54) Wet etching narrow trenches

(76) Inventors: Justin K. Brask, Portland, OR (US); Robert B. Turkot JR., Hillsboro, OR (US)

Correspondence Address: Timothy N. Trop,, TROP, PRUNER & HU, P.C., STE 100, 8554 KATY FWY, HOUSTON, TX, 77024-1841, US

(21) Appl. No.: 10/272,624

(22) Filed: Oct. 17, 2002

(51) Int. Cl. H01L 21/311

(52) U.S. Cl. 438/694

(57) ABSTRACT

Fill material in narrow, high aspect ratio trenches may be removed using wet etching in the presence of sonication. The use of sonication breaks up capillary forces, surface tension, and concentration gradient differentials to enable effective etching of the fill material in such narrow trenches.

### BACKGROUND

This invention relates generally to the fabrication of integrated circuits.

In a variety of integrated circuit fabrication operations, it may be desirable to remove material from trenches using wet etching. However, when the trenches are extremely narrow and have high aspect ratios, it has been found to be difficult to remove material from these trenches.

Basically, what happens is that only the very upper portion of the trench material is removed. The etchant does not penetrate downwardly to remove all the material from the trench.

Thus, there is a need for better ways to wet etch narrow, high aspect ratio trenches.

### BRIEF DESCRIPTION OF THE DRAWINGS

FIG. 1 is a greatly enlarged, partial cross-sectional view of a semiconductor wafer in accordance with one embodiment of the present invention;

FIG. 2 is a schematic depiction of the wafer in a wet etch bath in accordance with one embodiment of the present invention; and

FIG. 3 is a greatly enlarged, partial cross-sectional view of the wafer at a subsequent stage in accordance with one embodiment of the present invention.

### DETAILED DESCRIPTION

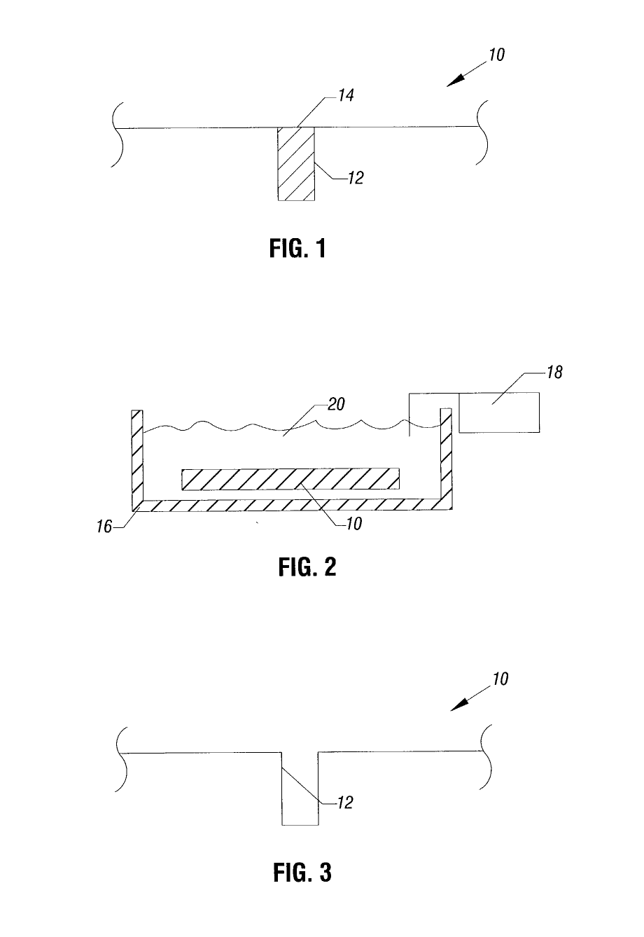

Referring to FIG. 1, a semiconductor wafer may have a trench 12 filled with a fill material 14. The trench 12 may have a width of 30 nanometers or less and an aspect ratio of depth to width of at least four to one.

The inventors of the present invention have determined that as a result of capillary forces, surface tension, and concentration gradient differentials, wet chemical etches are ineffective to etch such narrow, high aspect ratio trenches. However, through the use of ultra or megasonic energy, these forces and differentials may be overcome, resulting in efficient etching of the fill material 14.

Referring to FIG. 2, the wafer 10, having the trench 12 thereon, may be immersed in a wet etch bath 20 using any conventional wet etch material. The bath may be excited using a mega- or ultrasonic source 18. The source 18 may use a piezoelectric driver that operates in, but is not limited to, the frequency range of 300 to 1000 kilohertz, dissipating approximately, but is not limited to, 5 to 10 watts per square centimeter, in some embodiments. The provision of sonication has been found to be effective in breaking up the capillary forces, surface tension, and gradient differentials, allowing the etching process to penetrate deep into narrow trenches 12.

Thus, referring to FIG. 3, the high aspect ratio, narrow trench 12 may be cleaned using the techniques described herein in some embodiments. In one embodiment, the fill material 14 may be polysilicon and the material 15, in which the trench 12 is formed, may be an interlayer dielectric, such as silicon dioxide.

In accordance with one application of the present invention, the trench filler material 14 may be used as a place holder. For example, initially a blanket layer of polysilicon may be formed over a wafer. The polysilicon may be dry etched and patterned to form relatively narrow lines. An interlayer dielectric may then be deposited over the patterned polysilicon. The interlayer dielectric may be polished to expose the polysilicon lines. At this point, the polysilicon lines then amount to a trench filler in trenches effectively defined within the interlayer dielectric. At this point, the polysilicon filler material 14 may then be removed using the techniques described herein. The remaining trench 12, shown in FIG. 3, may then be filled with another material.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
exposing a wafer having a filled trench to a wet etching solution; and
while the wafer is exposed to said wet etching solution, applying sonic energy to said solution.

2. The method of claim 1 including applying sonic energy in the range of 300 to 1000 kilohertz.

3. The method of claim 1 including dissipating between 5 and 10 watts per square centimeter.

4. The method of claim 1 including forming a trench having a width dimension of 30 nanometers or less.

5. The method of claim 1 including forming a trench that has a ratio of trench depth to width of at least four.

6. A method comprising:
forming a filled trench structure;
applying a wet etch solution to the wafer having a filled trench structure; and
applying sonic energy to said solution.

7. The method of claim 6 including applying sonic energy in the range of 300 to 1000 kilohertz.

8. The method of claim 6 including dissipating between 5 and 10 watts per square centimeter of energy in applying sonic energy.

9. The method of claim 6 including forming a trench having a width dimension of 30 nanometers or less.

10. The method of claim 6 including forming a trench having a depth to width ratio of at least four.

11. A method comprising:
forming a filled trench structure having a depth to width ratio of at least four and including a trench fill material;
exposing said fill material to a wet etching solution; and
while said trench is exposed to said wet etching solution, applying sonic energy to said solution.

12. The method of claim 11 including immersing a wafer containing said fill material in a wet etch solution.

13. The method of claim 11 including applying sonic energy in the range of 300 to 1000 kilohertz.

14. The method of claim 11 including dissipating between 5 and 10 watts per square centimeter of sonic energy.

15. The method of claim 11 including forming a trench by patterning deposited polysilicon and filling the region between the polysilicon with an interlayer dielectric.
